(19) United States
(12) Patent Application Publication
(10) Pub. No.: US 2024/0181562 A1
(43) Pub. Date: Jun. 6, 2024

(54) LASER PROCESSING APPARATUS

(71) Applicant: DISCO CORPORATION, Tokyo (JP)

(72) Inventor: Kazuki MORI, Tokyo (JP)

(21) Appl. No.: 18/526,079

(22) Filed: Dec. 1, 2023

(30) Foreign Application Priority Data
Dec. 2, 2022 (JP) 2022-193310

(51) Int. Cl. B23K 26/06; B23K 26/0622; B23K 26/067

(52) U.S. Cl. CPC B23K 26/0665; B23K 26/0622; B23K 26/0643; B23K 26/0648; B23K 26/067

(57) ABSTRACT

A laser processing apparatus has a laser beam applying unit including a laser oscillator for emitting a laser beam, an attenuator for regulating output power of the laser beam, a beam condenser for converging the laser beam and applying the converged laser beam to a workpiece held on a chuck table, a plane-of-polarization rotating unit disposed between the attenuator and the beam condenser for rotating the plane of polarization of the laser beam, a beam splitter disposed between the plane-of-polarization rotating unit and the attenuator for branching a returning beam reflected from an upper surface of the workpiece, an observing unit for observing the returning beam branched by the beam splitter, and an adjusting unit for adjusting the position of the beam condenser in order to focus a spot of the laser beam on the upper surface of the workpiece according to a configuration of the returning beam.

### BACKGROUND OF THE INVENTION

### Field of the Invention

The present invention relates to a laser processing apparatus.

### Description of the Related Art

Wafers with a plurality of devices such as integrated circuits (ICs) or large-scale integration (LSI) circuits constructed in respective areas demarcated in their face side by a grid of projected dicing lines are divided into individual device chips by a laser processing apparatus. The device chips will be used in electronic appliances such as cellular phones and personal computers (see, for example, Japanese Patent Laid-open No. Hei 10-305420).

The applicant of the present patent application has proposed a technology in connection with a laser processing apparatus for processing a workpiece such as an SiC ingot or an Si ingot with a laser beam to fabricate a wafer from the workpiece. According to the proposed processing technology, a laser beam emitted from a beam condenser is applied to an upper surface of the workpiece while its focused spot is positioned in the workpiece at a depth from the upper surface that corresponds to the thickness of the wafer to be fabricated from the workpiece, forming peel-off layers in the workpiece, and then the wafer is peeled off from the workpiece along the peel-off layers (see, for example, Japanese Patent Laid-open No. 2016-111143). In order to implement the processing technology, the beam condenser is positionally adjusted with respect to the upper surface of the workpiece before the laser beam is applied to the workpiece.

### SUMMARY OF THE INVENTION

As the laser processing apparatus is continuously operated to process the workpiece with the laser beam over time, some parts of the laser processing apparatus tend to suffer distortion due to heat, possibly bringing the upper surface of the workpiece and the actual focused spot of the laser beam out of proper positional relation. As a result, it may become difficult to position the focused spot of the laser beam properly with respect to the workpiece.

It is therefore an object of the present invention to provide a laser processing apparatus that is capable of adjusting the positional relation between an upper surface of a workpiece and a focused spot of a laser beam at all times even if the upper surface of the workpiece and the focused spot of the laser beam are brought out of proper positional relation as the laser processing apparatus is continuously operated to process the workpiece with the laser beam over time, thereby positioning the focused spot of the laser beam properly with respect to the workpiece.

In accordance with an aspect of the present invention, there is provided a laser beam processing apparatus including a chuck table for holding a workpiece thereon and a laser beam applying unit for applying a laser beam to the workpiece held on the chuck table, in which the laser beam applying unit includes a laser oscillator for emitting a laser beam, an attenuator for regulating output power of the laser beam, a beam condenser for converging the laser beam emitted by the laser oscillator and applying the converged laser beam to the workpiece held on the chuck table, a plane-of-polarization rotating unit disposed between the attenuator and the beam condenser for rotating the plane of polarization of the laser beam, a beam splitter disposed between the plane-of-polarization rotating unit and the attenuator for branching a returning beam reflected from an upper surface of the workpiece when the laser beam is applied thereto, an observing unit for observing the returning beam branched by the beam splitter, and an adjusting unit for adjusting the position of the beam condenser in order to focus a spot of the laser beam on the upper surface of the workpiece according to a configuration of the returning beam observed by the observing unit.

Preferably, the laser beam applying unit further includes a half-wave plate disposed between the beam splitter and the laser oscillator for adjusting the plane of polarization of the laser beam to convert the laser beam into a P-polarized beam with respect to the beam splitter, and an expander for adjusting the laser beam to a collimated beam. Preferably, the observing unit is a shearing interferometer.

The laser processing apparatus according to the present invention is capable of adjusting the position of the upper surface of the workpiece and the position of a focused spot of the laser beam at all times even if the position of the upper surface of the workpiece and the position of the focused spot of the laser beam are shifted out of alignment with each other as a laser processing process carried out on the laser processing apparatus progresses over time, and positioning the focused spot of the laser beam in a proper position with respect to the workpiece.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view of a laser processing apparatus according to an embodiment of the present invention;

FIG. 2 is a block diagram of an optical system of a laser beam applying unit of the laser processing apparatus illustrated in FIG. 1;

FIG. 3A is a side elevational view of an ingot to be processed by the laser processing apparatus illustrated in FIG. 1;

FIG. 3B is a plan view of the ingot illustrated in FIG. 3A;

FIG. 4A is a perspective view illustrating the manner in which a laser processing process for forming peel-off layers in the ingot is carried out on the laser processing apparatus illustrated in FIG. 1;

FIG. 4B is a cross-sectional view taken along line B-B of FIG. 4A;

FIG. 5A is a view illustrating the manner in which the focused spot of a laser beam is defocused above the upper surface of the ingot;

FIG. 5B is a view illustrating a striped pattern observed by an observing unit when the focused spot of the laser beam is defocused as illustrated in FIG. 5A;

FIG. 5C is a view illustrating a laser beam spot observed on the upper surface of the ingot by the observing unit when the focused spot of the laser beam is defocused as illustrated in FIG. 5A;

FIG. 6A is a view illustrating the manner in which the focused spot of the laser beam is defocused below the upper surface of the ingot;

FIG. 6B is a view illustrating a striped pattern observed by the observing unit when the focused spot of the laser beam is defocused as illustrated in FIG. 6A;

FIG. 6C is a view illustrating a laser beam spot observed on the upper surface of the ingot by the observing unit when the focused spot of the laser beam is defocused as illustrated in FIG. 6A;

FIG. 7A is a view illustrating the manner in which the focused spot of the laser beam is positioned on the upper surface of the ingot;

FIG. 7B is a view illustrating a striped pattern observed by the observing unit when the focused spot of the laser beam is focused on the upper surface of the ingot as illustrated in FIG. 7A; and

FIG. 7C is a view illustrating a laser beam spot observed on the upper surface of the ingot by the observing unit when the focused spot of the laser beam is focused on the upper surface of the ingot as illustrated in FIG. 7A.

### DETAILED DESCRIPTION OF THE PREFERRED EMBODIMENT

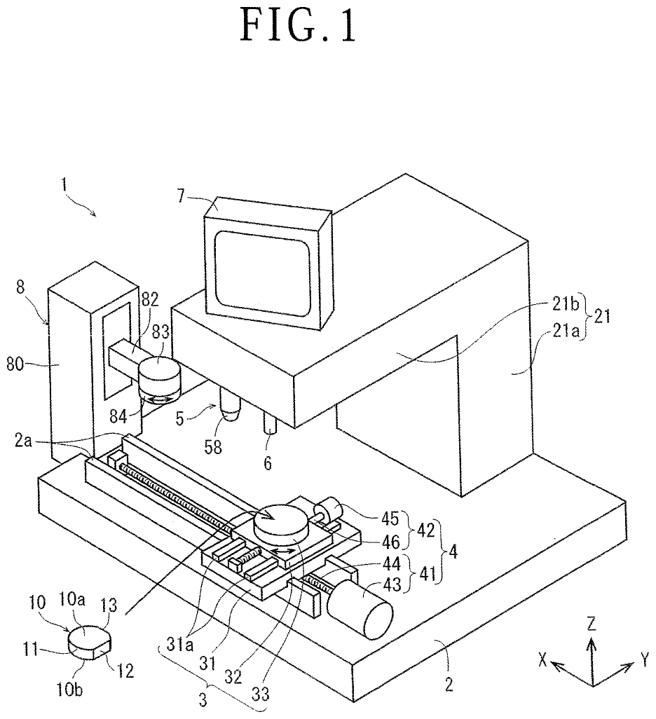

A laser processing apparatus according to a preferred embodiment of the present invention will be described in detail hereinbelow with reference to the accompanying drawings. FIG. 1 illustrates in perspective the laser processing apparatus, denoted by 1, according to the present embodiment. As illustrated in FIG. 1, the laser processing apparatus 1 includes at least a holding unit 3 for holding a workpiece, e.g., an ingot 10, thereon and a laser beam applying unit 5 for applying a laser beam to the ingot 10 held on the holding unit 3.

In FIG. 1, the laser processing apparatus 1 is illustrated in reference to a three-dimensional coordinate system having an X-axis, a Y-axis, and a Z-axis. The X-axis, indicated by an arrow X, and the Y-axis, indicated by an arrow Y, extend horizontally perpendicularly to each other. The Z-axis, indicated by an arrow Z, extends vertically perpendicularly to the X-axis and the Y-axis. The X-axis and the Y-axis jointly define a horizontal XY plane that lies essentially horizontally. The X-axis, the Y-axis, and the Z-axis are also illustrated in some other figures.

As illustrated in FIG. 1, the holding unit 3 includes an X-axis movable plate 31 movably mounted on a base 2 for movement along the X-axis, a Y-axis movable plate 32 movably mounted on the X-axis movable plate 31 for movement along the Y-axis, a chuck table 33 rotatably mounted on the Y-axis movable plate 32 for rotation about its central axis parallel to the Z-axis, and an unillustrated electric motor for rotating the chuck table 33 about its central axis.

The laser processing apparatus 1 also includes a moving assembly 4 for moving the holding unit 3. The moving assembly 4 includes an X-axis moving mechanism 41 and a Y-axis moving mechanism 42. The X-axis moving mechanism 41 has a ball screw 44 operatively coupled to the X-axis movable plate 31 and extending along the X-axis and an electric motor 43 for rotating the ball screw 44 about its central axis. The X-axis moving mechanism 41 operates as follows: The ball screw 44 converts the rotary motion of the electric motor 43 to linear motion, which is transmitted to the X-axis movable plate 31 to move the X-axis movable plate 31 along the X-axis on a pair of guide rails 2a mounted on the base 2 and extending along the X-axis.

The Y-axis moving mechanism 42 has a ball screw 46 operatively coupled to the Y-axis movable plate 32 and extending along the Y-axis and an electric motor 45 for rotating the ball screw 46 about its central axis. The Y-axis moving mechanism 42 operates as follows: The ball screw 46 converts the rotary motion of the electric motor 45 to linear motion, which is transmitted to the Y-axis movable plate 32 to move the Y-axis movable plate 32 along the Y-axis on a pair of guide rails 31a mounted on the X-axis movable plate 31 and extending along the Y-axis.

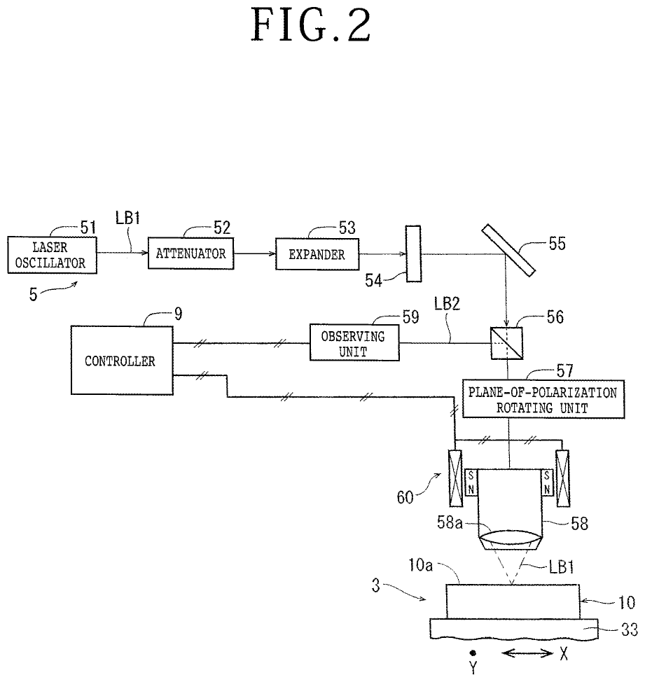

A frame 21 is disposed on the base 2 behind the moving assembly 4 along the Y-axis. The frame 21 includes a vertical wall 21a vertically erected on the base 2 and a horizontal wall 21b extending horizontally from an upper end portion of the vertical wall 21a along the Y-axis in overhanging relation to the holding unit 3 and the moving assembly 4. The horizontal wall 21b houses therein and supports thereon an optical system of the laser beam applying unit 5 and an image capturing unit 6. The optical system of the laser beam applying unit 5 includes a beam condenser 58 disposed on the lower surface of a distal end portion of the horizontal wall 21b. The image capturing unit 6 includes a portion disposed on the lower surface of the distal end portion of the horizontal wall 21b, adjacent to the beam condenser 58 along the X-axis. The image capturing unit 6 captures an image of the ingot 10 held on the holding unit 3. The captured image will be used in an alignment process for positioning the ingot 10 with respect to the beam condenser 58 and in a height detecting process for detecting the height of a first end face 10a, i.e., an upper surface, of the ingot 10 on the holding unit 3. The laser processing apparatus 1 further includes a separating unit 8 for peeling off a wafer from the ingot 10 along peel-off layers that are formed in the ingot 10 and that are to be described below, a controller 9 (see FIG. 2) for controlling various components of the laser processing apparatus 1, and a display unit 7 electrically connected to the controller 9.

The separating unit 8 includes a casing 80 shaped as a rectangular parallelepiped extending upwardly from the base 2 near ends of the guide rails 2a and an arm 82 extending along the X-axis from its proximal end vertically movably mounted on the casing 80. The casing 80 houses therein an unillustrated arm lifting and lowering mechanism that lifts and lowers the arm 82 along the Z-axis. An electric motor 83 that is attached to a distal end of the arm 82 has a lower surface on which a suction disk 84 is rotatably disposed. The suction disk 84 is coupled to an unillustrated drive shaft of the electric motor 83, so that the suction disk 84 can be rotated about its central axis along the Z-axis by the electric motor 83 when it is energized. The suction disk 84 has a plurality of unillustrated suction holes that are defined in a lower surface thereof and that are fluidly connected to unillustrated suction means via an unillustrated fluid channel. The suction disk 84 houses therein an unillustrated ultrasonic vibrating unit for applying ultrasonic vibrations to the lower surface of the suction disk 84.

FIG. 2 illustrates in block form the optical system of the laser beam applying unit 5. The laser beam applying unit 5 includes a laser oscillator 51 for emitting a laser beam LB1, an attenuator 52 for regulating the output power of the laser beam LB1, the beam condenser 58 that includes a condensing lens 58a for focusing the laser beam LB1 and applying the focused laser beam LB1 to the ingot 10 held on the chuck table 33 of the holding unit 3, a plane-of-polarization rotating unit 57 disposed between the attenuator 52 and the beam condenser 58 for rotating the plane of polarization of the laser beam LB1, a beam splitter 56 disposed between the plane-of-polarization rotating unit 57 and the attenuator 52 for branching a returning beam LB2 reflected from the first end face 10a as the upper surface of the ingot 10 when the laser beam LB1 is applied thereto, an observing unit 59 for observing the returning beam LB2 branched by the beam splitter 56, and an adjusting unit 60 for adjusting the position of the beam condenser 58 along the Z-axis in order to focus a spot of the laser beam LB1 on the first end face 10a of the ingot 10 according to the configuration of the returning beam LB2 observed by the observing unit 59. The plane-of-polarization rotating unit 57 according to the present embodiment represents means for rotating the plane of polarization of a linearly polarized beam applied thereto, and preferably is a known Faraday rotator, for example. However, the plane-of-polarization rotating unit 57 according to the present invention is not limited to such a Faraday rotator, and may alternatively be another component having the same function, e.g., a quarter-wave plate. The adjusting unit 60 may be a voice-coil motor or a linear motor, for example.

According to the present embodiment, the laser beam applying unit 5 includes, in addition to the components described above, a half-wave plate 54 disposed between the beam splitter 56 and the laser oscillator 51 for adjusting the plane of polarization of the laser beam LB1 to convert the laser beam LB1 into a P-polarized beam with respect to the beam splitter 56, an expander 53 for adjusting the laser beam LB1 to a collimated beam, and a reflecting mirror 55 disposed between the half-wave plate 54 and the beam splitter 56 for changing the direction of the optical path for the laser beam LB1.

The observing unit 59 is what is generally called a shearing interferometer, for example. The shearing interferometer refers to an interferometer capable of determining whether a beam applied thereto is a collimated beam or not, as described later. The observing unit 59 and the adjusting unit 60 are electrically connected to the controller 9. The returning beam LB2 reflected from the first end face 10a of the ingot 10 and branched by the beam splitter 56 has its configuration observed by the observing unit 59 and displayed on the display unit 7 by the controller 9. According to the configuration of the returning beam LB2 observed by the observing unit 59, the controller 9 energizes the adjusting unit 60 to adjust the position of the focused spot of the laser beam LB1.

The laser processing apparatus 1 according to the present embodiment is arranged as described above. The function and operation of the laser processing apparatus 1 will be described in detail below.

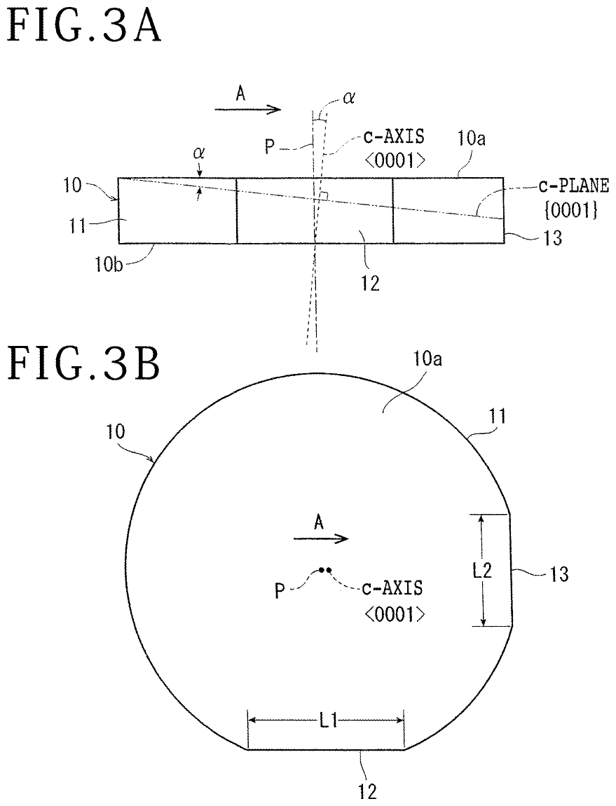

The workpiece to be processed by the laser processing apparatus 1 according to the present embodiment may be the ingot 10 illustrated in FIGS. 3A and 3B, for example. The ingot 10 illustrated in FIGS. 3A and 3B refers to an ingot of hexadecimal monocrystalline SiC having a diameter of approximately 100 mm, for example. The ingot 10 is of a substantially cylindrical shape as a whole, and has the first end face 10a as a substantially circular upper surface, a second end face 10b as a substantially circular lower surface opposite the first end face 10a, a circumferential surface 11 extending between the first end face 10a and the second end face 10b, a c-axis extending in a <0001> direction from the first end face 10a to the second end face 10b, and a c-plane as a {0001} plane perpendicular to the c-axis. As illustrated in FIG. 3A, the c-axis is inclined to a line P normal to the first end face 10a, and the c-plane and the first end face 10a form an off-angle α (for example, α=either one of 1, 3, and 6 degrees) therebetween. The direction in which the off-angle α is formed is represented by an arrow A. The circumferential surface 11 of the ingot 10 includes a first rectangular orientation flat 12 and a second rectangular orientation flat 13, each indicating a crystal orientation.

The first orientation flat 12 lies parallel to the direction A in which the off-angle α is formed and has a length L1 along the direction. The second orientation flat 13 lies in a direction perpendicular to the direction A in which the off-angle α is formed. As illustrated in FIG. 3B, which depicts the ingot 10 in plan, the second orientation flat 13 has a length L2 smaller than the length L1 of the first orientation flat 12 (L1>L2). Thus, the direction in which the off-angle α is formed can be determined by observing the different lengths L1 and L2 of the first and second orientation flats 12 and 13 regardless of whether the first end face 10a or the second end face 10b of the ingot 10 is observed. The workpiece that can be processed by the laser processing apparatus according to the present invention is not limited to the monocrystalline SiC ingot 10, and may be an ingot where the c-axis is not inclined to the first end face 10a and the off-angle α between the c-plane and the first end face 10a is of 0 degrees, i.e., the line P normal to the first end face 10a and the c-axis are aligned with each other. The workpiece may be of any configuration as long as the laser beam is applied thereto with the upper surface, i.e., the first end face 10a, used as a positional reference. For example, the workpiece may be a wafer fabricated from an ingot.

The laser processing apparatus 1 according to the present embodiment is operated to fabricate a wafer from the ingot 10. Specifically, the laser beam LB1 to be applied to the ingot 10 has a wavelength transmittable through SiC of the ingot 10. While the focused spot of the laser beam LB1 is being positioned in the ingot 10 at a depth from the first end face 10a that corresponds to the thickness of the wafer to be fabricated from the ingot 10, the laser beam LB1 is applied to the ingot 10 on the first end face 10a, forming peel-off layers in the ingot 10.

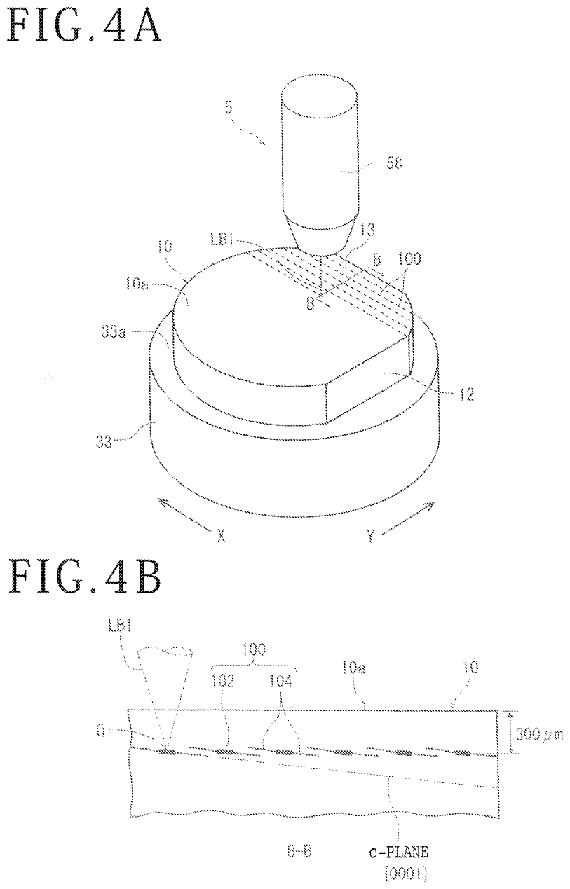

A laser processing process for forming peel-off layers in the ingot 10 to fabricate a wafer from the ingot 10 will be described in specific detail below. The ingot 10 is first delivered to the laser processing apparatus 1. The ingot 10 delivered to the laser processing apparatus 1 has its second end face 10b coated with an appropriate adhesive, e.g., an epoxy-resin-based adhesive, and placed and held on a flat upper surface 33a of the chuck table 33, as illustrated in FIG. 4A. The first end face 10a of the ingot 10 has been processed to a mirror finish by being ground and polished to remove surface irregularities therefrom.

Then, the image capturing unit 6 captures an image of the ingot 10 from above the first end face 10a, and the height detecting process is carried out to detect the height of the first end face 10a from the captured image. The alignment process is also performed using the capturing image. Specifically, according to the first orientation flat 12 and the second orientation flat 13 in the captured image of the ingot 10, the chuck table 33 is turned about its central axis and is moved by the X-axis moving mechanism 41 and the Y-axis moving mechanism 42, thereby adjusting the orientation of the ingot 10 to a predetermined orientation and adjusting the positions of the ingot 10 and the beam condenser 58 on the horizontal XY plane.

The orientation of the ingot 10 is adjusted to the predetermined orientation as follows: As illustrated in FIG. 4A, the second orientation flat 13 is aligned with the X-axis to bring the direction perpendicular to the direction A in which the off-angle α is formed into alignment with the X-axis and to hence bring the direction A in which the off-angle α is formed into alignment with the Y-axis. Next, according to the height of the first end face 10a of the ingot 10 detected from the captured image thereof, the controller 9 controls the adjusting unit 60 to lift or lower the beam condenser 58 and position the focused spot, denoted by Q in FIG. 4B, of the laser beam LB1 in the ingot 10 at a depth, e.g., 300 μm, from the first end face 10a that corresponds to the thickness of the wafer to be fabricated, as can be understood from a cross sectional view of FIG. 4B taken along line B-B of FIG. 4A. At the time of starting the laser processing process, the focused spot Q is accurately positioned at the depth referred to above because the laser beam applying unit 5 has not been adversely affected by heat. Then, while the chuck table 33 is being moved by the X-axis moving mechanism 41 at a predetermined processing feed speed along the X-axis that is aligned with the direction perpendicular to the direction A in which the off-angle α is formed, the laser beam LB1 that has a wavelength transmittable through sic of the ingot 10 is applied from the beam condenser 58 to the ingot 10, forming a separation band 102 in the ingot 10 at the depth of 300 μm.

The laser processing process is carried out under the laser processing conditions as follows:
Wavelength: 1064 nm
Repetitive frequency: 120 KHz
Average output power: 5 through 15 W
Processing feed speed: 785 mm/sec.

As described above, the laser beam applying unit 5 according to the present embodiment includes the attenuator 52. In the laser processing process for forming the separation band 102, the attenuator 52 regulates the output power of the laser beam LB1 to a level for modifying the inside of the ingot 10 to form a desirable separation band 102 therein.

The separation band 102 is formed in the ingot 10 when the laser beam LB1 is applied to the ingot 10 to separate SiC of the ingot 10 into Si and C and the laser beam LB1 that is applied next is absorbed by previously occurring C. As the chuck table 33 is processing-fed along the X-axis, the separation band 102 is continuously formed in the ingot 10 along the direction perpendicular to the direction A in which the off-angle α is formed. At the same time, cracks extend isotropically along the c-plane from the separation band 102, forming peel-off bands 104 over a predetermined width on opposite sides of the separation band 102. In the laser processing process for forming the separation band 102, the beam condenser 58, rather than the chuck table 33, may be moved at the predetermined processing feed speed along the X-axis.

After the separation band 102 and the peel-off bands 104 have been formed along the predetermined direction in the ingot 10, the Y-axis moving mechanism 42 is actuated to indexing-feed the chuck table 33 and move the ingot 10 in a relative relation to the focused spot Q of the laser beam LB1 along the Y-axis along the direction A in which the off-angle α is formed by a predetermined indexing distance ranging from 250 to 400 μm, for example, not exceeding the predetermined width of the peel-off bands 104. Then, the laser processing process is carried out again to form another separation band 102 spaced from the previously formed separation band 102 by the indexing distance in the ingot 10. The laser processing process and the process of indexing-feeding the chuck table 33 are alternately repeated to form successive separation bands 102 spaced the indexing distances along the direction A in which the off-angle α is formed and successive peel-off bands 104 extending as cracks isotropically along the c-plane from the separation bands 102. According to the present embodiment, since the off-angle α is formed between the line P normal to the first end face 10a of the ingot 10 and the c-axis inclined to the line P, the peel-off bands 104 that are adjacent to each other along the direction A in which the off-angle α is formed overlap each other vertically. The separation bands 102 and the peel-off bands 104 thus formed jointly make up a peel-off layer 100 in the ingot 10 at the depth corresponding to the wafer to be fabricated from the ingot 10 from the first end face 10a of the ingot 10. As the separation bands 102 are provided as modified layers in the ingot 10 and the peel-off bands 104 are provided as cracks extending from the separation bands 102, the peel-off layer 100 is of reduced mechanical strength.

After the peel-off layer 100 has been formed in the ingot 10, the wafer is separated from the ingot 10 along the peel-off layer 100 in a wafer separating process. For separating the wafer from the ingot 10, the X-axis moving mechanism 41 illustrated in FIG. 1 is actuated to move and position the chuck table 33 below the suction disk 84 of the separating unit 8. Next, the arm 82 of the separating unit 8 is lowered to bring the lower surface of the suction disk 84 into intimate contact with the first end face 10a of the ingot 10 on the chuck table 33. Then, the suction means that is fluidly connected to the suction disk 84 is actuated to develop a negative pressure that is transmitted to the lower surface of the suction disk 84, attracting the first end face 10a of the ingot 10 under suction. Subsequently, the ultrasonic vibrating unit housed in the suction disk 84 is actuated to apply ultrasonic vibrations to the lower surface of the suction disk 84, and the electric motor 83 is energized to rotate the suction disk 84 about its central axis, thereby separating the wafer from the ingot 10 along the peel-off layer 100. After the wafer has been separated from the ingot 10, the newly created surface of the ingot 10 from which the wafer has been separated, i.e., a new end face 10a, and the surface of the fabricated wafer that has been separated from the ingot 10 are planarized by grinding or polishing. Thereafter, the above laser processing process, the indexing-feeding process, and the wafer separating process are repeated to successively fabricate wafers from the ingot 10.

When the laser processing process for forming the peel-off layer 100 in the ingot 10 is repeatedly carried out, the laser beam applying unit 5 and mechanisms or components that support the laser beam applying unit 5 tend to be adversely affected by heat and hence distorted over time. Thus, even though the height of the first end face 10a of the ingot 10 has been measured and the adjusting unit 60 has been actuated to adjust the position of the focused spot Q, the first end face 10a of the ingot 10 and the focused spot Q of the laser beam LB1 may possibly be brought out of proper positional relation, with the result that the focused spot Q of the laser beam LB1 may not be positioned at a suitable position inside the ingot 10. The laser processing apparatus 1 according to the present embodiment in which the laser beam applying unit 5 has the optical system illustrated in FIG. 2 deals with the above problem as follows.

At the time when it is determined that the first end face 10a of the ingot 10 and the focused spot Q of the laser beam LB1 are brought out of proper positional relation upon elapse of a predetermined period of time in which the laser processing process for forming the peel-off layer 100 in the ingot 10 has been repeatedly carried out, or at any desired time, the laser processing process for forming the peel-off layer 100 in the ingot 10 is suspended, and the controller 9 operates in an adjustment mode for adjusting the positional relation between the first end face 10a of the ingot 10 and the focused spot Q of the laser beam LB1.

In the adjustment mode, the attenuator 52 of the laser beam applying unit 5 illustrated in FIG. 2 is actuated to regulate the laser beam LB1 emitted from the laser oscillator 51 to a very weak average output power, e.g., ranging from 0.01 through 0.03 W, small enough not to leave processing marks on the ingot 10. Then, the controller 9 adjusts the angle of rotation of the half-wave plate 54 to cause the laser beam LB1 that has passed through the half-wave plate 54 to pass through the beam splitter 56, i.e., to convert the laser beam LB1 into a P-polarized beam with respect to the beam splitter 56. Further, the controller 9 controls the plane-of-polarization rotating unit 57 to rotate the plane of polarization of the laser beam LB1 such that the returning beam LB2 reflected from the first end face 10a of the ingot 10 when the laser beam LB1 having passed through the beam splitter 56 is applied to the first end face 10a is branched by the beam splitter 56 toward the observing unit 59. Inasmuch as the plane-of-polarization rotating unit 57 in the form of a Faraday rotator rotates the plane of polarization through 45°, the returning beam LB2 that has been reflected by the first end face 10a and passed through the plane-of-polarization rotating unit 57 is an S-polarized beam with respect to the beam splitter 56.

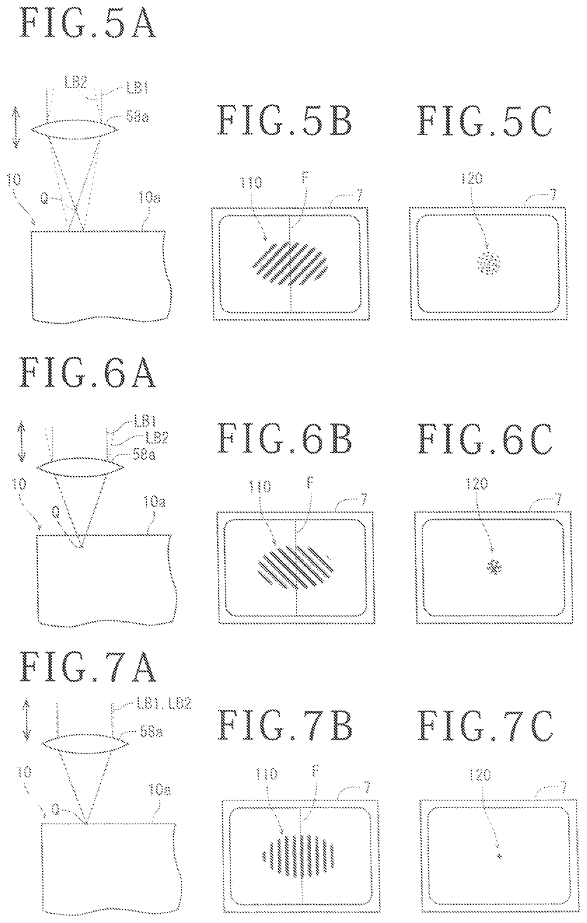

With the optical system of the laser beam applying unit 5 thus functioning, the controller 9 actuates the adjusting unit 60 to vertically move the focused spot Q of the laser beam LB1 in the vicinity of the first end face 10a of the ingot 10. The focused spot Q of the laser beam LB1 is now vertically moved between a defocused position (see FIG. 5A) above the first end face 10a and a defocused position (see FIG. 6A) below the first end face 10a. At this time, the controller 9 controls the observing unit 59 to observe the returning beam LB2 branched by the beam splitter 56.

The observing unit 59 according to the present embodiment is a shearing interferometer as described above. If a converged beam or a diffused beam is applied to the shearing interferometer, then the shearing interferometer produces a striped pattern inclined to a reference direction, and if a collimated beam is applied to the shearing interferometer, then the shearing interferometer produces a striped pattern aligned with a reference direction. Specifically, if the focused spot Q of the laser beam LB1 that has been converted into a collimated beam by the expander 53 is defocused above the first end face 10a, as illustrated in FIG. 5A, then since the returning beam LB2 that has been reflected by the first end face 10a and has passed through the condensing lens 58a is a converged beam, when the returning beam LB2 branched by the beam splitter 56 is applied to the observing unit 59, the observing unit 59 observes the returning beam LB2 as a striped pattern 110 (see FIG. 5B), which is displayed on the display unit 7 by the controller 9. As illustrated in FIG. 5B, the striped pattern 110 is inclined in a direction to a reference line F representing a reference direction.

On the other hand, if the focused spot Q of the laser beam LB1 is defocused below the first end face 10a, as illustrated in FIG. 6A, then since the returning beam LB2 that has been reflected by the first end face 10a and has passed through the condensing lens 58a is a diffused beam, when the returning beam LB2 branched by the beam splitter 56 is applied to the observing unit 59, the observing unit 59 observes the returning beam LB2 as a striped pattern 110 (see FIG. 6B), which is displayed on the display unit 7 by the controller 9. As illustrated in FIG. 6B, the striped pattern 110 is inclined in an opposite direction with respect to the reference line F.

The controller 9 controls the adjusting unit 60 to lift or lower the beam condenser 58 and hence the focused spot Q of the laser beam LB1 in the ingot 10 to change the inclination of the striped pattern 110 until it is aligned with the reference line F as illustrated in FIG. 7B, whereupon the first end face 10a of the ingot 10 and the focused spot Q of the laser beam LB1 are aligned with each other as illustrated in FIG. 7A. As described above, the controller 9 can recognize how much, or the amount by which, the first end face 10a of the ingot 10 and the focused spot Q of the laser beam LB1 are shifted out of proper positional relation. Once the controller 9 has recognized the amount by which the first end face 10a of the ingot 10 and the focused spot Q of the laser beam LB1 are shifted out of proper positional relation, the controller 9 stores the recognized amount as a corrective quantity. The controller 9 can then control the adjusting unit 60 according to the stored corrective quantity, after which the adjustment mode comes to an end. The angles of the converged and diffused beams illustrated in FIGS. 5A and 6A are exaggerated for illustrative purposes, and are different from actual angles.

The adjustment mode can be automatically performed according to control programs stored in the controller 9. The adjustment mode can be performed periodically while the laser processing process progresses, or at any desired times. According to the present invention, however, the adjustment mode may be performed manually by the operator who visually observes the inclination of the striped pattern 110.

According to the present embodiment, a shearing interferometer, for example, is used as the observing unit 59. However, the present invention is not limited to such details. Rather than a shearing interferometer, a charge-coupled device (CCD) image sensor for observing the spot of the returning beam LB2 may be used as the observing unit 59. The laser beam applying unit 5 where a CCD image sensor is used as the observing unit 59 operates as follows: If the focused spot Q of the laser beam LB1 is defocused above the first end face 10a of the ingot 10, then since the laser beam LB1 forms a relatively large beam spot on the first end face 10a, as compared to a case in which the focused spot Q is in a just-focused state, a spot 120 captured by the CCD image sensor and displayed on the display unit 7 has a relatively large diameter, as illustrated in FIG. 5C, so that the luminance of the spot 120 per unit area is observed as being of a relatively low level. If the focused spot Q of the laser beam LB1 is defocused below the first end face 10a of the ingot 10, then since the laser beam LB1 also forms a relatively large beam spot on the first end face 10a, the spot 120 captured by the CCD image sensor and displayed on the display unit 7 also has a relatively large diameter, as illustrated in FIG. 6C, so that the luminance of the spot 120 per unit area is observed as being of a relatively low level. On the other hand, if the focused spot Q of the laser beam LB1 and the first end face 10a of the ingot 10 are aligned with each other, the laser beam LB1 forms a relatively small beam spot on the first end face 10a, and the spot 120 captured by the CCD image sensor and displayed on the display unit 7 has a minimum diameter, as illustrated in FIG. 7C, so that the luminance of the spot 120 per unit area is observed as being of a maximum level.

In the adjustment mode that uses a CCD image sensor as the observing unit 59, as with the adjustment mode that uses a shearing interferometer as the observing unit 59, the controller 9 controls the adjusting unit 60 to vertically adjust the focused spot Q of the laser beam LB1 and observes the spot 120 illustrated in FIG. 5C or 6C to find the position of the focused spot Q where the spot 120 observed by the CCD image sensor is minimum and its luminance is maximum as illustrated in FIG. 7C. Consequently, the controller 9 can recognize the vertical position of the beam condenser 58 that keeps the first end face 10a of the ingot 10 and the focused spot Q of the laser beam LB1 in alignment with each other, and hence the amount by which the first end face 10a of the ingot 10 and the focused spot Q of the laser beam LB1 are out of proper positional relation to each other, as with the adjustment mode that uses a shearing interferometer as the observing unit 59.

According to the present embodiment, even if the upper surface of the workpiece and the focused spot of the laser beam are shifted out of proper positional relation as the laser processing process progresses over time, the upper surface of the workpiece and the focused spot of the laser beam can be positionally adjusted at all times, making it possible to position the focused spot of the laser beam in a proper position with respect to the workpiece. In the above embodiment, it has been described that the upper surface of the workpiece and the focused spot of the laser beam are shifted out of proper positional relation due to the laser beam applying unit being adversely affected by heat. However, the present invention is effective regardless of the reasons why the upper surface of the workpiece and the focused spot of the laser beam are positionally shifted out of alignment with each other. For example, the present invention addresses a situation where the upper surface of the workpiece and the focused spot of the laser beam are positionally shifted out of alignment with each other due to aging of the laser beam applying unit or other components.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A laser processing apparatus comprising:
a chuck table for holding a workpiece thereon; and
a laser beam applying unit for applying a laser beam to the workpiece held on the chuck table,
wherein the laser beam applying unit includes:
a laser oscillator for emitting a laser beam,
an attenuator for regulating output power of the laser beam,
a beam condenser for converging the laser beam emitted by the laser oscillator and applying the converged laser beam to the workpiece held on the chuck table,
a plane-of-polarization rotating unit disposed between the attenuator and the beam condenser for rotating a plane of polarization of the laser beam,
a beam splitter disposed between the plane-of-polarization rotating unit and the attenuator for branching a returning beam reflected from an upper surface of the workpiece when the laser beam is applied thereto,
an observing unit for observing the returning beam branched by the beam splitter, and
an adjusting unit for adjusting a position of the beam condenser in order to focus a spot of the laser beam on the upper surface of the workpiece according to a configuration of the returning beam observed by the observing unit.

2. The laser processing apparatus according to claim 1, wherein the laser beam applying unit further includes:
a half-wave plate disposed between the beam splitter and the laser oscillator for adjusting the plane of polarization of the laser beam to convert the laser beam into a P-polarized beam with respect to the beam splitter, and
an expander for adjusting the laser beam to a collimated beam.

3. The laser processing apparatus according to claim 1, wherein the observing unit is a shearing interferometer.
